(19) United States
(12) Patent Application Publication
(10) Pub. No.: US 2006/0270183 A1
(43) Pub. Date: Nov. 30, 2006

(54) Isolation structure and method of forming the same

(75) Inventors: Dae-Woong Kim, Seoul (KR); Kyung-Tae Jang, Seoul (KR); Seung-Heon Lee, Seoul (KR); Jun-Won Lee, Anyang-si (KR); Jung-Hoon Chae, Yongin-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/434,145

(22) Filed: May 16, 2006

(30) Foreign Application Priority Data
May 27, 2005 (KR) 2005-44870

(51) Int. Cl. H01L 21/76; H01L 29/00

(52) U.S. Cl. 438/424; 257/499

(57) ABSTRACT

An isolation structure may include a trench formed on a surface of a substrate. A first isolation pattern may be provided on an inner face of the trench to define an auxiliary trench. A second isolation pattern may be provided on the first isolation pattern to partially fill the auxiliary trench. A third isolation pattern may be provided on the second isolation pattern to fill up the auxiliary trench. The second isolation pattern may have an etching selectivity with respect to the first isolation pattern.

### PRIORITY STATEMENT

This application claims benefit of priority under 35 U.S.C. § 119 from Korean Patent Application No. 2005-44870 filed on May 27, 2005, the disclosure of which is incorporated herein by reference in its entirety.

### BACKGROUND

1. Field of the Invention

Example embodiment of the present invention relate generally to an isolation structure and a method of forming the isolation structure. More particularly, example embodiments of the present invention relate to an isolation structure that may have a reduced number of voids and a method of forming the isolation structure.

2. Description of the Related Art

Semiconductor device, which may be integrated, may implement an isolation process to provide isolation characteristics in a relatively small area. Example isolation processes include a local oxidation of silicon (LOCOS) process and a trench isolation process. The LOCOS process may achieve relatively good isolation characteristics. In addition, the LOCOS process may be relatively simple. However, a relatively large area may be required to perform the LOCOS process. In addition, a bird's beak, which may be formed in the LOCOS process, may narrow down an active region. The trench isolation process may achieve good isolation characteristics in a relatively small area. In the trench isolation process, a substrate may be etched using a silicon nitride pattern as an etching mask to form a trench on a surface of the substrate. An oxide layer, which may fill the trench, may be formed on the substrate. A chemical mechanical polishing (CMP) process may be performed until the substrate is exposed so that an isolation layer may be formed in the trench.

Conventional trench isolation processes are generally thought to be acceptable. However, they are not with shortcomings. For example, if the trench has a relatively high aspect ratio, the isolation layer filling up the trench may have voids.

If a sidewall of the trench is substantially vertical and/or if the trench includes portions having different aspect ratios, then voids may be generated in the isolation layer filling up the trench.

If the trench includes a first trench having a first aspect ratio and a second trench having a second aspect ratio that is larger than the first aspect ratio, then the oxide layer may fill up the second trench before the first trench. That is, the first trench may be partially filled with the oxide layer while the oxide layer may fill up the second trench. If a deposition process is performed until the first trench is fully filled with the oxide layer, an overhang may be formed at an upper potion of the first trench. The overhang may cause voids in the first trench.

Conventional methods have been implemented to suppress the voids. In one conventional method, a silicon oxide layer and a polycrystalline silicon layer may be formed in a trench. The polycrystalline silicon layer may be thermally treated to remove the voids. However, if the voids are relatively small and/or the polycrystalline silicon layer has only a few voids, the polycrystalline silicon layer may exceedingly expand in thermally treating the polycrystalline silicon layer. Such overexpansion may crack the isolation layer.

If the isolation layer has voids, the isolation characteristics of the isolation layer may be deteriorated. If conductive material is diffused into the voids, active regions may be inadvertently electrically connected to one another. Thus, the semiconductor device may have an operation failure.

### SUMMARY

According to an example embodiment, an isolation structure may include a trench formed on a surface of a substrate. A first isolation pattern may be provided on an inner face of the trench to define an auxiliary trench. A second isolation pattern may be provided on the first isolation pattern to partially fill the auxiliary trench. The second isolation pattern may have an etching selectivity with respect to the first isolation pattern. A third isolation pattern may be provided on the second isolation pattern to fill up the auxiliary trench.

According to another example embodiment, a method may involve etching a substrate using a mask pattern as an etching mask to form a trench on a surface of the substrate. A first isolation layer may be formed on the mask pattern and an inner face of the trench to define an auxiliary trench. A second isolation pattern may be formed on the first isolation layer to partially fill the auxiliary trench. The second isolation pattern may have an etching selectively with respect to the first isolation layer. A third isolation layer may be formed on the second isolation pattern to fill up the auxiliary trench. The third isolation layer and the first isolation layer may be planarized until the mask pattern is exposed to form a first isolation pattern and a third isolation pattern in the trench. The mask pattern may be removed.

According to another example embodiment, an isolation structure may include a trench formed on a surface of a substrate. The trench may include a first trench portion having a first aspect ratio and a second trench portion having a second aspect ratio that is larger than the first aspect ratio. A first isolation member may include a first isolation pattern provided on an inner face of the first trench portion to define an auxiliary trench. A second isolation pattern may be provided on the first isolation pattern to partially fill the auxiliary trench. The second isolation pattern may have an etching selectively with the first isolation layer pattern. A third isolation pattern may be provided on the second isolation pattern to fill up the auxiliary trench. A second isolation member corresponding to a fourth isolation pattern may fill up the second trench portion.

According to another example embodiment, a method may involve forming a trench on a surface of a substrate using a mask pattern. The trench may include a first trench portion having a first aspect ratio and a second trench portion having a second aspect ratio that is larger than the first aspect ratio. A first isolation layer may be formed to fill up the second trench portion. The first isolation layer may be formed on the mask pattern and an inner face of the first trench portion to partially fill the first trench portion. The first isolation layer may define an auxiliary trench over the first trench portion. A second isolation pattern may be formed on the first isolation layer to partially fill the auxiliary trench. The second isolation pattern may have an etching selectivity with respect to the first isolation layer. A third isolation layer may be formed to fill up the auxiliary trench. The third isolation layer and the first isolation layer may be planarized until the mask pattern is exposed to form a third isolation pattern and a first isolation pattern. The mask pattern may be removed.

According to another example embodiment, an isolation structure may include a trench defining an active region of a substrate. Silicon oxide may be provided in the trench. Silicon nitride may be embedded in the silicon oxide.

### BRIEF DESCRIPTION OF THE DRAWINGS

Example, non-limiting embodiments of the present invention will become readily apparent by reference to the following detailed description when considered in conjunction with the accompanying drawings in which:

FIG. 1 is a cross-sectional view of an isolation structure in accordance with an example, non-limiting embodiment of the present invention.

FIGS. 2 to 5 are cross-sectional views of example methods that may be implemented to manufacture the isolation structure in FIG. 1.

FIG. 6 is a cross-sectional view of isolation structures that may be implemented in a dynamic random access memory (DRAM) device in accordance with an example, non-limiting embodiment of the present invention.

FIG. 7 is a plan view of an isolation region and an active region of the DRAM device in FIG. 6.

FIGS. 8 to 13 are cross-sectional views of example methods that may be implemented to manufacture the isolation structure in FIG. 6.

### DESCRIPTION OF EXAMPLE, NON-LIMITING EMBODIMENTS

Example, non-limiting embodiments of the present invention will be described with reference to the accompanying drawings. The present invention may, however, be embodied in many different forms and should not be construed as limited to the example embodiments set forth herein. Rather, the disclosed embodiments are provided so that disclosure of the present invention will be thorough and complete, and will fully convey the scope of the present invention to those skilled in the art. The principles and features of this invention may be employed in varied and numerous embodiments without departing from the scope of the present invention. In the drawings, the size and relative sizes of layers and regions may be exaggerated for clarity. The drawings are not to scale. Like reference numerals refer to like elements throughout.

It will be understood that when an element or layer is referred to as being “on”, “connected to” and/or “coupled to” another element or layer, the element or layer may be directly on, connected and/or coupled to the other element or layer or intervening elements or layers may be present. In contrast, when an element is referred to as being “directly on,” “directly connected to” and/or “directly coupled to” another element or layer, there may be no intervening elements or layers present. As used herein, the term “and/or” may include any and all combinations of one or more of the associated listed items.

It will be understood that, although the terms first, second, etc. may be used herein to describe various elements, components, regions, layers and/or sections. These elements, components, regions, layers and/or sections should not be limited by these terms. These terms may be used to distinguish one element, component, region, layer and/or section from another element, component, region, layer and/or section. For example, a first element, component, region, layer and/or section discussed below could be termed a second element, component, region, layer and/or section without departing from the teachings of the present invention.

Spatially relative terms, such as “beneath,” “below,” “lower,” “above,” “upper” and the like may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as “below” and/or “beneath” other elements or features would then be oriented “above” the other elements or features. The device may be otherwise oriented (rotated 90 degrees or at other orientations) and the spatially relative descriptors used herein interpreted accordingly.

The terminology used herein is for the purpose of describing particular embodiments only and is not intended to limit of the invention. As used herein, the singular terms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not predlude the presence and/or addition of one or more other features, integers, steps, operations, elements, components, and/or groups thereof.

Unless otherwise defined, all terms (including technical and scientific terms) used herein may have the same meaning as what is commonly understood by one of ordinary skill in the art. It will be further understood that terms, such as those defined in commonly used dictionaries, should be interpreted as having a meaning that is consistent with their meaning in the context of the relevant art and will not be interpreted in an idealized and/or overly formal sense unless expressly so defined herein.

Embodiments of the present invention are described with reference to cross-section illustrations that are schematic illustrations of idealized embodiments of the present invention. As such, variations from the shapes of the illustrations as a result, for example, of manufacturing techniques and/or tolerances, may be expected. Thus, embodiments of the present invention should not be construed as limited to the particular shapes of regions illustrated herein but are to include deviations in shapes that result, for example, from manufacturing. For example, an etched region illustrated as a rectangle may have rounded or curved features. Thus, the regions illustrated in the figures are schematic in nature of a device and are not intended to limit the scope of the present invention.

In the present disclosure, references are made to recesses and/or trenches that are “on” a substrate. It will be understood that these references encompass both a recess (or a trench) that is physically above the substrate such as, for example, the open area between two gate patterns that are formed on top of a substrate as well as recesses (or a trench) that is formed in, or hollowed out of, the top surface of the substrate such as, for example, the recess/trench that may be formed in a semiconductor substrate as part of conventional trench isolation processes.

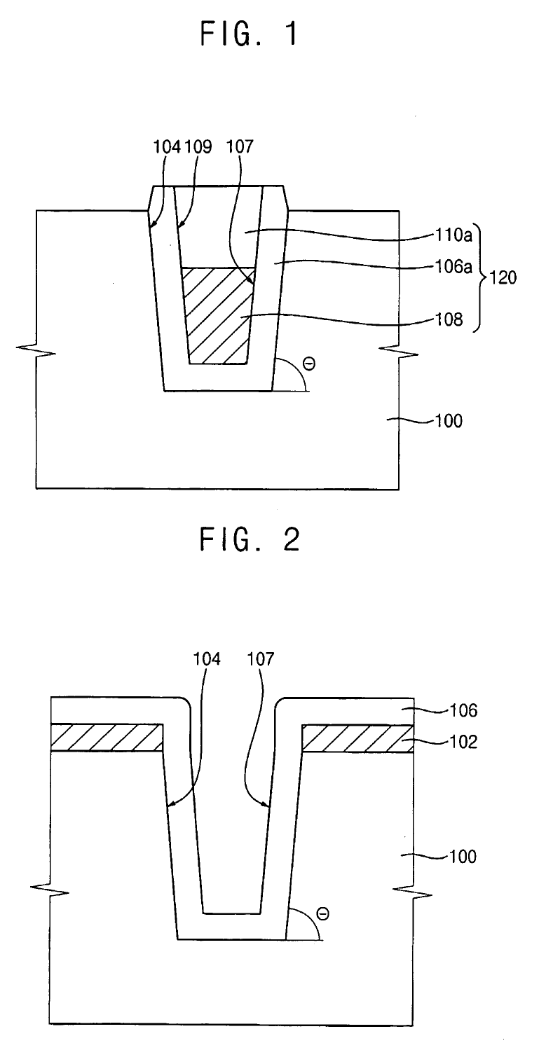

FIG. 1 is a cross-sectional view of an isolation structure 120 in accordance with an example, non-limiting embodiment of the present invention.

Referring to FIG. 1, a trench 104 may be formed on a surface of a substrate 100. A sidewall of the trench 104 may form an external angle (θ) of about 80° to about 90° (for example) with respect to a bottom face of the trench 104. That is, the external angle (θ) may be an acute angle formed between the sidewall of the trench 104 and an imaginary plan outwardly expanding from the bottom face of the trench 104.

A first isolation pattern 106a may be provided on the sidewalls and the bottom face of the trench 104. The first isolation pattern 106 may have a substantially uniform thickness. That is, the first isolation pattern 106a may conform to an inner face of the trench 104. The first isolation pattern 106a may define a first auxiliary trench 107. The first isolation pattern 106a may be formed by partially removing a silicon oxide layer. The silicon oxide layer may include (for example) high density plasma chemical vapor deposition (HDP-CVD) oxide, thermal oxidation oxide, tetraethyloxysilane (TEOS) oxide and/or undoped silicate glass (USG) oxide. These materials may be used alone or in combination. The HDP-CVD oxide is oxide obtained by an HDP-CVD process. The thermal oxidation oxide may be oxide obtained by a thermal oxidation process. The TEOS oxide may be oxide obtained by using a silicon source including TEOS. If the first isolation pattern 106a is formed by using the USG, the first isolation pattern 106 may more efficiently conform to the inner face of the trench 104 even though the trench 104 may have a relatively high aspect ratio. This is because the USG may have a relatively superior step coverage.

A second isolation pattern 108 may be provided on a bottom face of the first auxiliary trench 107 defined by the first isolation pattern 106a. The second isolation pattern 108 may partially fill the first auxiliary trench 107. That is, the second isolation pattern 108 may fill up a lower portion of the first auxiliary trench 107. The second isolation pattern 108 may have an etching selectivity with respect to the first isolation pattern 106a. By way of example only, the second isolation pattern 108 may be fabricated from silicon nitride and/or undoped polysilicon. The second isolation pattern 108 may be formed by a low pressure chemical vapor deposition (LPCVD) process, for example. If the second isolation pattern 108 is formed by the LPCVD process, the second isolation layer may have superior step coverage. An upper face of the second isolation pattern 108 and the sidewalls of the first isolation pattern 106a may together define a second auxiliary trench 109 over the second isolation pattern 108.

A third isolation pattern 110a may be provided on the second isolation pattern 108. The third isolation pattern 110a may fill up the second auxiliary trench 109. Thus, the isolation structure 120 may include the first isolation pattern 106a, the second isolation pattern 108 and the third isolation pattern 110a provided in the trench 104. The third isolation pattern 110a may be formed by partially removing a silicon oxide layer. The silicon oxide layer may include (for example) HDP-CVD oxide, thermal oxidation oxide, TEOS oxide and/or USG. These materials may be used alone or in combination.

FIGS. 2 to 5 are cross-sectional views of example methods that may be implemented to manufacture the isolation structure in FIG. 1.

Referring to FIG. 2, a mask pattern 102 may be provided on the substrate 100 so that an isolation region may be selectively exposed. For example, a silicon nitride layer may be provided on the substrate 100. The silicon nitride layer may be partially removed to form the mask pattern 102.

The substrate 100 may be etched using the mask pattern 102 as an etching mask so that a trench 104 may be provided on a surface of the substrate 100. The isolation structure may be provided in the trench 104 by succeeding processes.

So that the isolation structure may have improved isolation characteristics in a relatively small area, the trench 104 may have a relatively small upper width and a relatively large depth. Also, an external angle (θ) between a sidewall of the trench 104 and a bottom face of the trench 104 may be a substantially right angle. For example, the external angle (θ) may be about 80° to about 90°.

A first isolation layer 106 including an insulation material such as silicon oxide (for example) may be provided on an inner face of the trench 104 and an upper face of the mask pattern 102. The first isolation layer 106 may conform to the inner face of the trench 104 and the upper face of the mask pattern 102. The first isolation layer 106 may be formed by using HDP-CVD oxide, thermal oxidation oxide, TEOS oxide and/or USG. These materials may be used alone or in combination. If the first isolation layer 106 is formed using the USG, the first isolation layer 106 may efficiently conform to the inner face of the trench 104 and the upper face of the hard mask pattern 102 even though the trench 104 may have a relatively high aspect ratio. This is because the USG may have relatively superior step coverage. The first isolation layer 106 may define a first auxiliary trench 107 having a width substantially smaller than that of the trench 104.

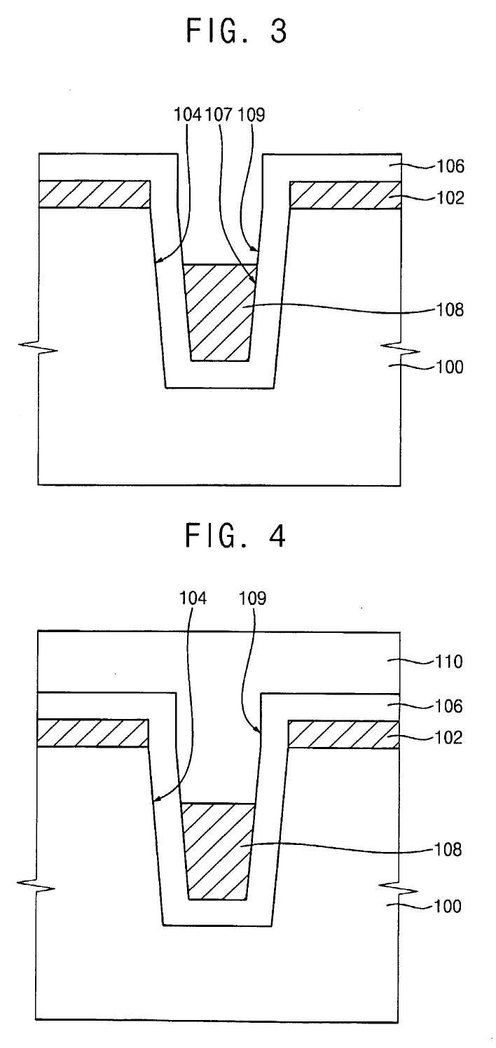

Referring to FIG. 3, a second isolation pattern 108 may be provided on the bottom face of the first auxiliary trench 107 defined by the first isolation layer 106. The first auxiliary trench 107 may be partially filled with the second isolation pattern 108. That is, the second isolation pattern 108 may fill a lower portion of the first auxiliary trench 107. The second isolation pattern 108 may have an etching selectivity with respect to the first isolation pattern 106a. An upper face of the second isolation pattern 108 may be lower than at least an upper face of the substrate 100. Here, the upper face of the second isolation pattern 108 and sidewalls of the first isolation layer 106 may together define a second auxiliary trench 109 over the second isolation pattern 108.

Hereinafter, processes that may be implemented to form the second isolation layer pattern 108 will be described.

A second isolation layer (not shown) may be provided in the first auxiliary trench 107. The second isolation layer may fill up the first auxiliary trench 107. The second isolation layer may have an etching selectivity with respect to the first isolation layer 106. For example, the second isolation layer may include silicon nitride and/or undoped polysilicon. The second isolation layer may be formed by an LPCVD process, for example.

An upper portion of the second isolation layer may be removed by an etch-back process so that the second isolation pattern 108 partially filling the first auxiliary trench 107 may be formed. That is, the second isolation pattern 108 may fill up a lower portion of the first auxiliary trench 107.

The mask pattern 102 and the first isolation layer 106 may be only slightly removed in the etch-back process. If a void is generated in the second isolation layer, the void may be opened by the etch-back process. Upon opening, the void may become a recess that may be filled with insulation material. Thus, a failure of a semiconductor device (the failure being due to the void) may be prevented.

If an upper portion of the second isolation pattern 108 becomes outwardly exposed over the isolation region in succeeding processes, the upper portion of the second isolation pattern 108 may generate particles. Thus, a third isolation layer 110 (See FIG. 4) may be provided on the second isolation pattern 108. The third isolation layer 110 may fully cover the upper portion of the second isolation pattern 108. So that the third isolation layer 110 may fully cover the upper portion of the second isolation pattern 108, the upper face of the second isolation pattern 108 may be lower than at least the upper surface of the substrate 100.

If the third isolation layer 100 becomes recessed in succeeding processes, openings may be formed through the third isolation layer 10 and the second isolation pattern 108 may be exposed through the openings. Thus, particles may be generated. To suppress the particles, the third isolation layer 110 may have a thickness substantially larger than a recess margin of the third isolation layer 100. This may prevent the formation openings through the third isolation layer 110 even when the third isolation layer 110 is recessed. That is, the upper face of the second isolation pattern 108 may be lower than the upper face of the substrate 100 by a predetermined interval.

For example, if the third isolation pattern 100a is recessed in the succeeding process by a depth of about 1,000 Å, the predetermined interval may be larger than about 1,000 Å.

Referring to FIG. 4, the third isolation layer 110 may be provided on the second isolation pattern 108. The third isolation layer 110 may fill up the second auxiliary trench 109. The third isolation layer 110 may include silicon oxide, for example. The third isolation layer 110 may be formed by using HDP-CVD oxide, thermal oxidation oxide, TEOS oxide and/or USG. These materials may be used alone or in combination.

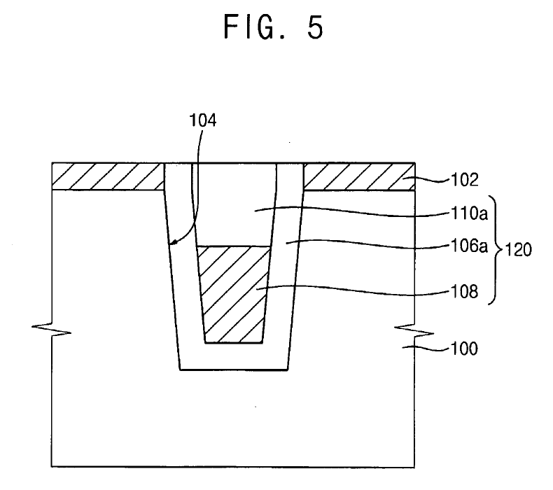

Referring to FIG. 5, the third isolation layer 110 and the first isolation layer 106 may be planarized by a planarization process until the mask pattern 102 is exposed. In this way, the first isolation pattern 106a, the second isolation pattern 108 and the third isolation pattern 110a may be formed in the trench 104. The planarization process may be a chemical mechanical polishing (CMP) process, for example.

The mask pattern 102 may be removed so that an isolation structure 120 including the first isolation pattern 106a, the second isolation pattern 108 and the third isolation pattern 110a may be provided in the trench 104.

As noted above, the isolation structure 120 may have a reduced number of voids and substantially vertical sidewalls. Thus, the isolation characteristics of the isolation structure 120 may be improved. In addition, the chances of an operation failure may be reduced in the semiconductor device including the isolation structure 120.

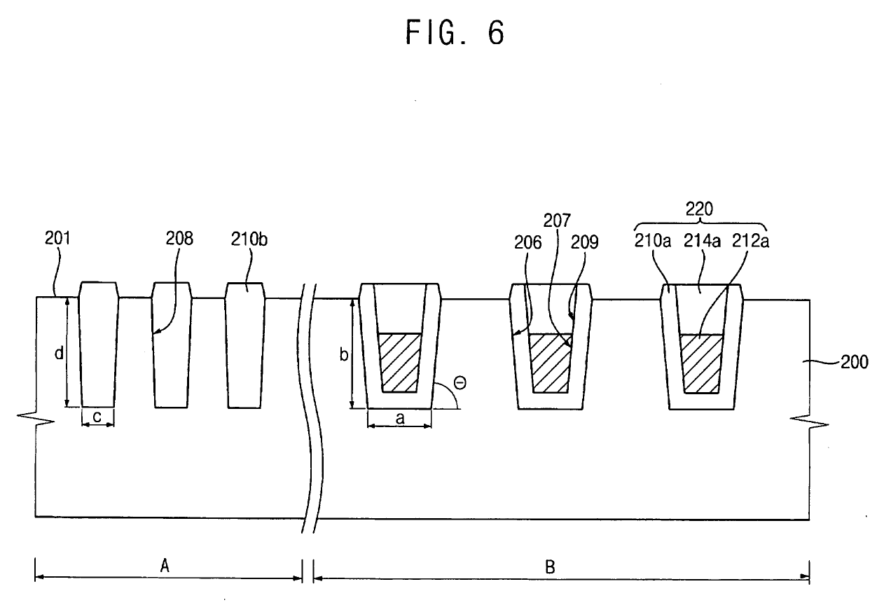

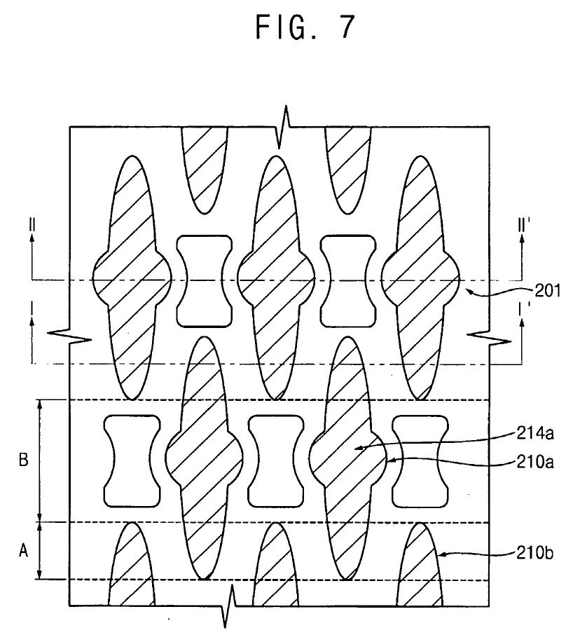

FIG. 6 is a cross-sectional view of isolation structures that may be implemented in a dynamic random access memory (DRAM) device in accordance with an example, non-limiting embodiment of the present invention. FIG. 7 is a plan view of an isolation region and an active region of the DRAM device in FIG. 6.

A region “A” in FIG. 6 is a cross-sectional view taken along the line I-I′ in FIG. 7. A region “B” in FIG. 6 is a cross-sectional view taken along the line II-II′ in FIG. 7.

Referring to FIGS. 6 and 7, a first trench 206 and a second trench 208 may be formed on a surface of a substrate 200. The first trench 206 may have a first aspect ratio (b/a), and the second trench 208 may have a second aspect ratio (d/c). The second aspect ratio may be larger than the first aspect ratio. By way of example only, the second aspect ratio may be no less than about 1.3 times the first aspect ratio, and the second aspect ratio may be no less than about 3.

The first trench 206 may be contiguous with the second trench 208. In addition, a depth of the first trench 206 may be substantially the same as that of the second trench 208.

The first trench 206 may be formed on a first surface portion of the substrate 200. The first surface portion may be positioned between bit line contact regions onto which contacts electrically connected to bit lines may be provided. The second trench 208 may be formed on a second surface portion of the substrate 200. The second portion may be positioned between capacitor contact regions onto which contacts electrically connected to capacitors may be provided.

An aspect ratio of a trench in which an isolation layer is to be formed may be large. In addition, a width of an upper portion of the trench may be narrow. Thus, to obtain a relative large depth of the trench, a sidewall of the trench may be substantially vertical.

A DRAM device may implement a recessed transistor. If a silicon fence is provided on a sidewall of a recess in which a gate electrode of the recessed transistor is formed, the DRAM device may not efficiently operate. Thus, it is desirable that a trench has a sidewall that is substantially vertical. For example, sidewalls of the first and the second trenches 206 and 208 may have angles of inclination of about 80° to about 90°.

An inner wall oxide layer (not shown) may be provided on inner faces of the first and the second trenches 206 and 208. A nitride liner (not shown) may be provided on the inner wall oxide layer. The nitride liner may (for example) reduce a stress due to material filling up the first and the second trenches 206 and 208. The nitride liner may (for example) prevent impurities from being diffused into an isolation region.

A first isolation pattern 210a may be provided on an inner face of the first trench 206. The first isolation pattern 210a may include silicon oxide. For example, the first isolation pattern 210a may be formed by partially removing a silicon oxide layer. The silicon oxide layer may be formed by using HDP-CVD oxide, thermal oxidation oxide, TEOS oxide and/or USG. These materials may be used alone or in combination.

If the first isolation pattern 210a is formed by using the USG, the first isolation pattern 210a may efficiently conform to the sidewalls and the bottom faces of the first trench 206 and the second trench 208 even though the first trench 206 and the second trench 208 may have relatively high aspect ratios. This is because the USG may have relatively superior step coverage.

The first isolation pattern 210a, which may be provided on an inner face of the first trench 206, may define a first auxiliary trench 207 having a width that is narrower than that of the first trench 206.

A second isolation pattern 212a may be provided on a bottom face of the first auxiliary trench 207. The auxiliary trench 207 may be partially filled with the second isolation pattern 212a. That is, the second isolation pattern 212a may fill up a lower portion of the first auxiliary trench 207. The second isolation pattern 212a may have an etching selectively with respect to the first isolation pattern 210a. The second isolation pattern 212a may include silicon nitride and undoped polysilicon. The sidewalls of the first isolation pattern 210a and an upper face of the second isolation pattern 212a may together define a second auxiliary trench 209 over the second isolation pattern 212a.

A third isolation pattern 214a may be provided in the second auxiliary trench 209. The third isolation pattern 214a may be formed using silicon oxide. For example, the third isolation pattern 214a may be formed by partially removing a silicon oxide layer. The silicon oxide layer may be formed by using HDP-CVD oxide, thermal oxidation oxide, TEOS oxide and/or USG. These materials may be used alone or in combination.

As illustrated in FIG. 6, a first isolation member 220, which may include the first isolation pattern 210a, the second isolation pattern 212a and the third isolation pattern 214a, may fill up the first trench 206. The second isolation pattern 212a may have an etching selectivity with respect to the first isolation pattern 210a.

A fourth isolation pattern 210b may be provided in the second trench 201. The fourth isolation pattern 210b may include material substantially the same as that included in the first isolation pattern 210a. For example, the fourth isolation pattern 210b may include silicon oxide. As illustrated in FIG. 6, a second isolation member may correspond to the fourth isolation pattern 210b provided in the second trench 208.

Hereinafter, methods that may be implemented to manufacture an isolation structure including the first and the second isolation members will be described.

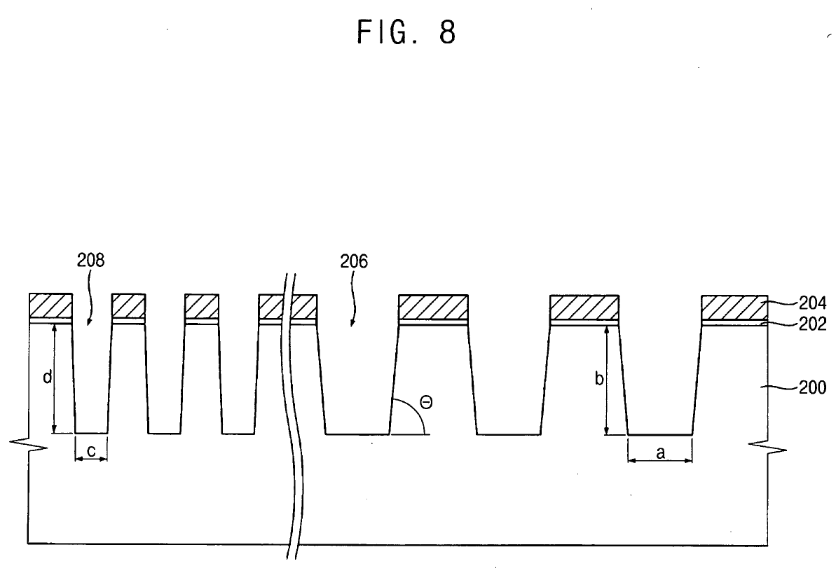

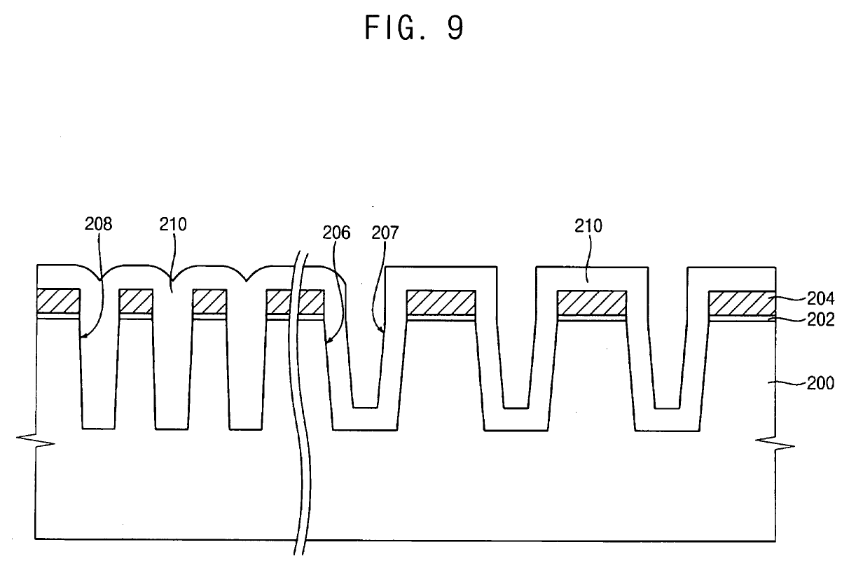

FIGS. 8 to 13 are cross-sectional views of methods that may be implemented to manufacture the isolation structure in FIG. 6.

Referring to FIG. 8, a buffer oxide layer (not shown) and a mask layer (not shown) may be provided on a substrate 200. A thermal oxidation process may be performed on the substrate 200 so that the buffer oxide layer may be formed. The mask layer may include silicon nitride, for example. If the mask layer including silicon nitride is provided directly on the substrate 200, a stress due to the mask layer may be applied to the substrate 200. Thus, the buffer oxide layer may be provided between the substrate 200 and the mask layer to reduce the stress. The mask layer including silicon nitride may be formed by a LPCVD process, for example.

The mask layer and the buffer oxide layer may be etched to form a mask pattern 204 and a buffer oxide pattern 202. The isolation region may be exposed through the mask pattern 204 and the buffer oxide pattern 202.

The substrate 200 may be etched using the mask pattern 204 as an etching mask so that a first trench 206 having a first aspect ratio and a second trench 208 having a second aspect ratio may be formed on a surface of the substrate 200. The second aspect ratio may be greater than the first aspect ratio. By way of example only, the second aspect ratio may be at least about 1.3 times the first aspect ratio, and the second aspect ratio may be at least about 3.

The first trench 206 may be contiguous with the second trench 208. A depth of the first trench 206 may be substantially the same as that of the second trench 208.

In some embodiments, a recessed transistor may be provided on an active region 201 (see FIGS. 6 and 7). The recessed transistor may have a gate electrode partially lodged in the active region 201. That is, a recess formed on a surface of the active region 201 may be filled with a lower portion of the gate electrode. When the recess is formed, a silicon fence may be removed from a sidewall of the recess. To remove the silicon fence, it is helpful that a sidewall of an isolation structure defining the active region 201 is substantially vertical. For this reason, the sidewalls of the first and the second trenches 206 and 208 may have angles of inclination of about 80° to about 90°, for example.

By way of example only, the first and the second trenches 206 and 208 may be formed by a dry etching process using plasma. The plasma may cause damage to surfaces of the first and the second trenches 206 and 208 in the dry etching process. To cure the damage, a trench inner wall oxide layer (not shown) may be formed on inner surfaces of the first and the second trenches 206 and 208. The trench inner wall oxide layer may be formed by performing a thermal oxidation process (for example) on the inner surfaces of the first and the second trenches 206 and 208. The trench inner wall oxide layer may have a relatively thin thickness of about 30 Å to about 150 Å, for example.

A nitride liner (not shown) may be provided on a surface of the inner wall oxide layer and an upper face of the mask pattern 204. The nitride liner may have a relatively thin thickness of about 30 Å to about 300 Å, for example. The nitride liner may reduce stress applied to silicon oxide in the first and the second isolation members. The nitride layer may prevent impurities from being diffused into the isolation region through the nitride layer.

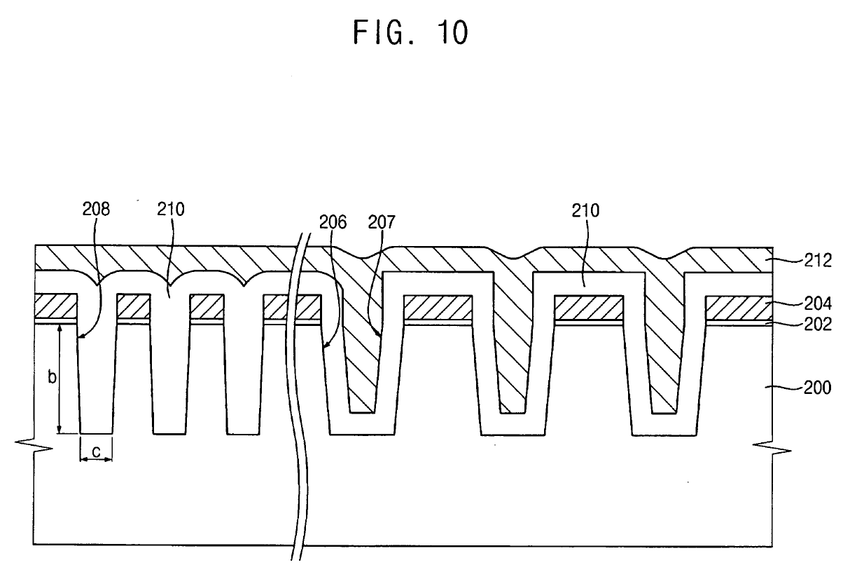

Referring to FIG. 9, a first isolation layer 210 may be provided on the hard mask pattern 204 and inner faces of the first and the second trenches 206 and 208. The second trench 208 may be fully filled with the first isolation layer 201. The second trench 208 may be only partially filled with the first isolation layer 201.

The first isolation layer 210 may include silicon oxide, which may be capable of filling up the second trench 208 having a relatively large aspect ratio and without voids. By way of example only, the first isolation layer 210 including silicon oxide may be formed by using HDP-CVD oxide, thermal oxidation oxide, TEOS oxide and/or USG. These materials may be used alone or in combination. If the first isolation layer 210 is formed using the USG, the voids may be efficiently suppressed in the second trench 208. This is because the USG may have relatively superior step coverage.

If the first trench 206 having a relatively small aspect ratio is fully filled with the first isolation layer 210, voids due to overhangs may be formed in the first trench 206. Thus, the first isolation layer 210 may be provided on the inner face of the first trench 206 and an upper face of the mask pattern 204 to partially fill the first trench 206.

A first auxiliary trench 207 may be defined by the first isolation layer 210 in the first trench 206. The first auxiliary trench 207 may have a width smaller than that of the first trench 206.

Referring to FIG. 10, a second isolation layer 212 may be provided on the first isolation layer to fill up the first auxiliary trench 207. The second isolation layer 212 may have an etching selectivity with respect to the first isolation layer 210. By way of example only, the second isolation layer 212 may include silicon nitride and/or undoped polysilicon. The second isolation layer 212 may be formed by an LPCVD process, for example. The second isolation layer 212 formed by the LPCVD process may have relatively superior step coverage.

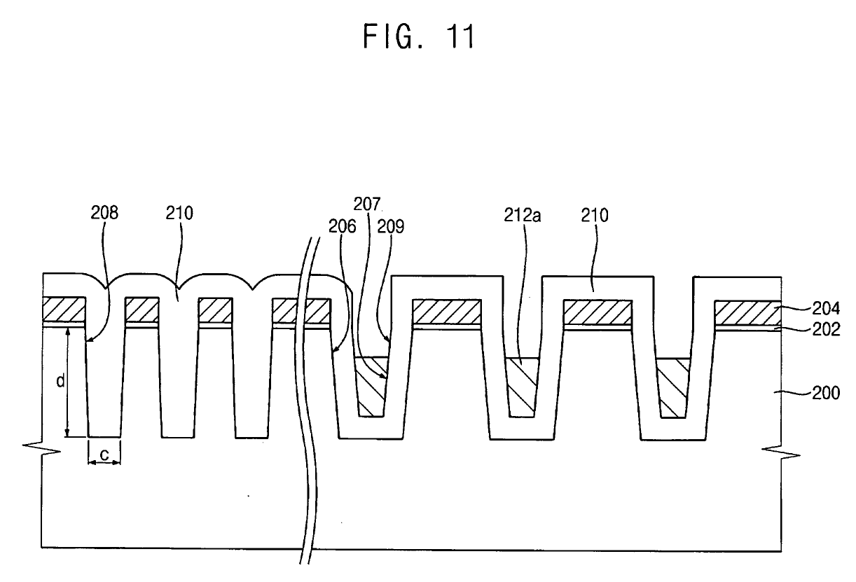

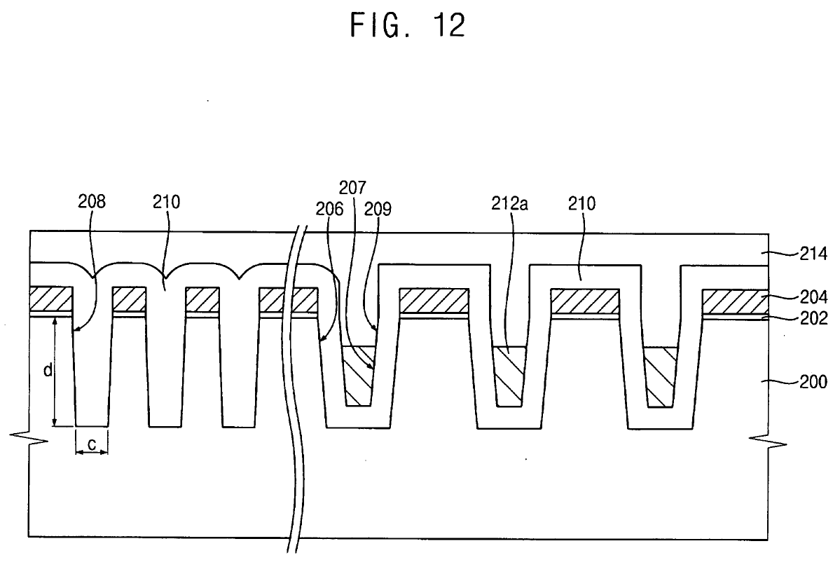

Referring to FIG. 11, the second isolation layer 212 is partially removed until an upper portion of the first isolation layer 210, the upper portion being positioned over the mask pattern 204 and upper sidewalls of the first and the second trenches 206 and 208, may be exposed so that a second isolation pattern 212a may be formed. Here, an upper face of the second isolation pattern 212a may be lower than an upper face of the substrate 200.

A second auxiliary trench 209 may be formed in the first trench 206 by the second isolation pattern 212a.

The second isolation layer 212 may be partially removed by an etch-back process, for example. In the etch-back process, the second isolation layer 212 may be selectively removed so that the first isolation layer 210 may be only slightly removed.

In the etch-back process, portions of the first isolation layer 210, the portions being positioned over the mask pattern 204 and the second trench 208, may be firstly exposed. Portions of the second isolation layer 212, the portions being positioned in the first trench 206, may be partially removed. Because the second isolation layer 212 may be selectively etched in the etch-back process, the first isolation layer 210 may be only slightly removed in the etch-back process.

As illustrated in FIG. 11, the second isolation pattern 212a may fill a lower portion of the first auxiliary trench 207, the lower portion where voids may be generated. In this way, void generation may be efficiently suppressed by virtue of the second isolation pattern 212.

If an upper portion of the second isolation pattern 212a is outwardly exposed, the upper portion of the second isolation layer pattern 212a may generate particles. Thus, a third isolation pattern 214a (See FIG. 13) may be provided on the upper portion of the second isolation pattern 212a. The third isolation pattern 214a may cover the upper portion of the second isolation pattern 212a so that the upper portion of the second isolation pattern 212a may not be outwardly exposed over the isolation region. So that the third isolation pattern 214a may fully cover the upper portion of the second isolation layer pattern 212a, the upper face of the second isolation pattern 212a may be lower than at least the upper surface of the substrate 200. If the third isolation pattern 214a is recessed in succeeding processes, openings may be formed through the third isolation pattern 214a so that the upper portion of the second isolation pattern 212a may be exposed through the openings. To suppress the particles, the third isolation pattern 214a may have a thickness substantially larger than a recess margin of the third isolation pattern 214a. For example, the upper face of second isolation pattern 212a may be lower than the upper face of the substrate 200 by a predetermined interval. In this case, the openings may not be formed even though the third isolation pattern 214a may be recessed.

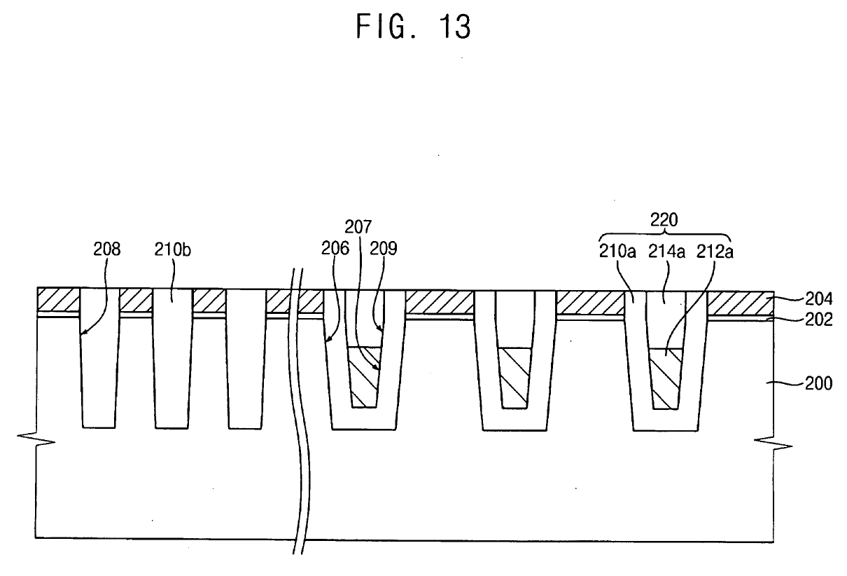

Referring to FIG. 12, a third isolation layer 214 may be provide on the first isolation layer 210 and the second isolation pattern 212a to fill up the second auxiliary trench 209. The third isolation layer 214 may include silicon oxide, for example. The third isolation layer 214 may be formed by using HDP-CVD oxide, thermal oxidation oxide, TEOS oxide and/or USG. These materials may be used alone or in combination. The third isolation layer 214 formed by using the HDP-CVD oxide may have relatively superior step coverage.

Referring to FIG. 13, the third isolation layer 214 and the first isolation layer 210 may be planarized until the mask pattern 204 may be exposed, so that a first isolation member 220 and a second isolation member that corresponds to the fourth isolation pattern 210b may be formed in the first trench 206 and the second trench 208, respectively. The first isolation member 220, which may include the first isolation pattern 210a, the second isolation pattern 212a and the third isolation pattern 214a, may be provided in the first trench 206. The second isolation member, which may correspond to the fourth isolation pattern 210b, may be provided in the second trench 208. The first and the fourth isolation patterns 210a and 210b may be formed by performing a planarizing process such as a CMP process (for example) on the first isolation layer 210. The first isolation pattern 210a may include insulation material substantially the same as that included in the fourth isolation pattern 210b.

The mask pattern 204 may be removed. Thus, an isolation structure including the first isolation member 220 and the second isolation member that corresponds to the fourth isolation pattern 210b may be formed.

Although it is not particularly illustrated in the drawings, the active region 201 may be partially removed so that the recess in which the gate electrode of the recessed transistor is to be formed in succeeding processes may be formed. Because sidewalls of the isolation structures are substantially vertical, the silicon fence may be hardly formed on the sidewalls of the isolation structure.

The recess may be formed by a patterning process for forming a mask pattern, an etching process and a cleaning process, for example. In the above-described processes, the third isolation pattern 214a may be partially recessed. Because the third isolation pattern 214a may have a sufficient thickness, openings may not be formed through the third isolation pattern 214a even when the third isolation layer pattern 214a may be partially recessed. Thus, the second isolation pattern 212a may not be outwardly exposed over the isolation region.

As described above, the isolation structure may fill the first and the second trenches 206 and 208 that have different aspect ratios without voids. Although the sidewalls of the first and the second trenches 206 and 208 may be substantially vertical, voids may not be generated in the isolation structure.

According to example embodiment of the present invention, an isolation layer filling a trench may have a reduced number of voids. Thus, isolation characteristics of a semiconductor device including the isolation layer may be improved. In addition, chances of an operation failure of the semiconductor device may be reduced.

The foregoing is illustrative of the present invention and is not to be construed as limiting thereof. Although example embodiments of the invention have been described, those skilled in the art will readily appreciate that many modifications are possible without materially departing from the spirit and scope of this invention. Accordingly, all such modifications are intended to be included within the scope of this invention as defined in the claims.

What is claimed is:

1. An isolation structure comprising:
a trench formed on a surface of a substrate;
a first isolation pattern provided on an inner face of the trench to define an auxiliary trench;
a second isolation pattern provided on the first isolation pattern to partially fill the auxiliary trench, the second isolation pattern having an etching selectivity with respect to the first isolation pattern; and
a third isolation pattern provided on the second isolation pattern to fill up the auxiliary trench.

2. The isolation structure of claim 1, wherein a sidewall of the trench has an angle of inclination of about 80° to about 90°.

3. The isolation structure of claim 1, wherein the first isolation pattern includes at least one of high density plasma chemical vapor deposition oxide, thermal oxidation oxide, tetraethyloxysilane oxide and undoped silicate glass.

4. The isolation structure of claim 1, wherein the second isolation pattern includes at least one of silicon nitride and undoped polysilicon.

5. The isolation structure of claim 1, wherein the third isolation pattern includes silicon oxide.

6. A method comprising:
etching a substrate using a mask pattern as an etching mask to form a trench on a surface of the substrate;
forming a first isolation layer on the mask pattern and an inner face of the trench to define an auxiliary trench;
forming a second isolation pattern on the first isolation layer to partially fill the auxiliary trench, the second isolation pattern having an etching selectively with respect to the first isolation layer;
forming a third isolation layer on the second isolation pattern to fill up the auxiliary trench;
planarizing the third isolation layer and the first isolation layer until the mask pattern is exposed to form a first isolation pattern and a third isolation pattern in the trench; and
removing the mask pattern.

7. The method of claim 6, wherein a sidewall of the trench has an angle of inclination of about 80° to about 90°.

8. The method of claim 6, wherein the first isolation layer includes at least one of high density plasma chemical vapor deposition oxide, thermal oxidation oxide, tetraethyloxysilane oxide and undoped silicate glass.

9. The method of claim 6, wherein forming the second isolation pattern comprises:
forming a second isolation layer to fill up the auxiliary trench; and
etching the second isolation layer until portions of the first isolation layer are exposed, the portions being positioned on the mask pattern and upper portions of sidewalls of the auxiliary trench.

10. The method of claim 9, wherein etching the second isolation layer involves an etch-back process.

11. The method of claim 9, wherein the second isolation layer includes at least one of silicon nitride and undoped polysilicon.

12. The method of claim 9, wherein the second isolation layer is formed by a low pressure chemical vapor deposition process.

13. The method of claim 6, wherein the third isolation pattern has a thickness that is larger than a recess margin of the third isolation layer.

14. The method of claim 6, wherein the third isolation layer includes silicon oxide.

15. An isolation structure comprising:
a trench formed on a surface of a substrate, the trench including a first trench portion having a first aspect ratio and a second trench portion having a second aspect ratio that is larger than the first aspect ratio;
a first isolation member including
a first isolation pattern provided on an inner face of the first trench portion to define an auxiliary trench,
a second isolation pattern provided on the first isolation pattern to partially fill the auxiliary trench, the second isolation pattern having an etching selectively with the first isolation layer pattern, and
a third isolation pattern provided on the second isolation pattern to fill up the auxiliary trench; and
a second isolation member corresponding to a fourth isolation pattern filling up the second trench portion.

16. The isolation structure of claim 15, wherein sidewalls of the first and the second trench portions have angles of inclination of about 80° to about 90°.

17. The isolation structure of claim 15, wherein the first isolation pattern includes at least one of high density plasma chemical vapor deposition oxide, thermal oxidation oxide, tetraethyloxysilane oxide and undoped silicate glass.

18. The isolation structure of claim 15, wherein the first isolation pattern includes the same material as that included in the fourth isolation pattern.

19. The isolation structure of claim 15, wherein the second isolation pattern includes at least one of silicon nitride and undoped polysilicon.

20. The isolation structure of claim 15, wherein the third isolation pattern includes silicon oxide.

21. The isolation structure of claim 15, wherein the first trench portion is contiguous with the second trench portion.

22. A method comprising:
forming a trench on a surface of a substrate using a mask pattern, the trench including a first trench portion having a first aspect ratio and a second trench portion having a second aspect ratio that is larger than the first aspect ratio;
forming a first isolation layer to fill up the second trench portion, the first isolation layer being formed on the mask pattern and an inner face of the first trench portion to partially fill the first trench portion, the first isolation layer defining an auxiliary trench over the first trench portion;
forming a second isolation pattern on the first isolation layer to partially fill the auxiliary trench, the second isolation pattern having an etching selectivity with respect to the first isolation layer;
forming a third isolation layer to fill up the auxiliary trench;
planarizing the third isolation layer and the first isolation layer until the mask pattern is exposed to form a third isolation pattern and a first isolation pattern; and
removing the mask pattern.

23. The method of claim 22, wherein sidewalls of the first and the second trench portions have angles of inclination of about 80° to about 90°.

24. The method of claim 22, wherein the first isolation layer includes at least one of high density plasma chemical vapor deposition oxide, thermal oxidation oxide, tetraethyloxysilane oxide and undoped silicate glass.

25. The method of claim 22, wherein forming the second isolation pattern comprises:
forming a second isolation layer to fill up the auxiliary trench; and
etching the second isolation layer until portions of the first isolation layer are exposed, the portions being positioned on the mask pattern and upper portions of sidewalls of the auxiliary trench.

26. The method of claim 25, wherein the second isolation layer is etched by an etch-back process.

27. The method of claim 25, wherein the second isolation layer includes at least one silicon nitride and undoped polysilicon.

28. The method of claim 25, wherein the second isolation layer is formed by a low pressure chemical vapor deposition process.

29. The method of claim 22, wherein the third isolation layer is formed using silicon oxide.

30. The method of claim 22, wherein the third isolation pattern has a thickness that is larger than a recess margin of the third isolation layer.

31. An isolation structure comprising:
a trench defining an active region of a substrate;
silicon oxide provided in the trench; and
silicon nitride embedded in the silicon oxide.
